(19) United States
(12) Patent Application Publication
(10) Pub. No.: US 2020/0173423 A1
(43) Pub. Date: Jun. 4, 2020

(54) LIGHTNING DETECTION AND MEASUREMENT SYSTEM AND METHOD FOR LOCATION DETECTION OF LIGHTNING STRIKES ON A WIND TURBINE BLADE

(71) Applicant: POLYTECH A/S, Bramming (DK)

(72) Inventors: Mads KIRKEGAARD, Ribe (DK); Richard BAKER, Lichfield, Staffordshire (GB)

(21) Appl. No.: 16/627,150

(22) PCT Filed: Jul. 10, 2018
(86) PCT No.: PCT/IB2018/055079

§ 371 Date: Dec. 27, 2019

(30) Foreign Application Priority Data
Jul. 11, 2017 (DK) PA201700409

(51) Int. Cl. F03D 80/30; G01R 29/08; G01R 19/15; F03D 17/00; G08C 17/00; H02G 13/00

(52) U.S. Cl. CPC F03D 80/30; G01R 29/0842; G01R 19/15; F05B 2260/80; G08C 17/00; H02G 13/60; F03D 17/00

(57) ABSTRACT

The lightning detection system includes a lightning ground conductor of a turbine blade, several lightning receptors connected to the lightning ground conductor, and several individual lightning detectors measuring a lightning parameter indicative of the magnitude of a lightning current. A main ground conductor lightning detector measures a magnitude of any lightning current leaving the blade through the lightning ground conductor. Each individual lightning detector includes an individual sensor element, an individual microprocessor, an individual memory storage, an individual wireless communication module, and an individual power supply including a battery and a power harvesting device. The system includes a central wireless communication module communicating directly with one or more of the individual wireless communication modules, and each individual wireless communication module communicates directly with at least one of the other individual wireless communication modules and/or the central wireless communication module.

The present invention relates to a lightning detection and measurement system adapted to detect the location of lightning strikes on a wind turbine blade, the system including a blade lightning ground conductor adapted to extend in the longitudinal direction of a wind turbine blade, a number of lightning receptors electrically connected to and distributed along the length of the blade lightning ground conductor, a number of individual lightning detectors distributed along the length of the blade lightning ground conductor and each being adapted to measure a lightning parameter indicative of the magnitude of a lightning current flowing through a corresponding individual electrically conductive part of a connection between a lightning receptor and the blade lightning ground conductor or of the blade lightning ground conductor when a lightning strikes one or more of the lightning receptors, and a main blade ground conductor lightning detector adapted to measure at least a magnitude of any lightning current leaving the blade through the blade lightning ground conductor when a lightning strikes one or more of the lightning receptors.

Today, lightning detection and measurement systems do exist, but solutions that have been put into practice are limited to measuring the bulk current from the event at the root end of the wind turbine blade. Generally, these systems are not capable of detecting where on the wind turbine blade the strike occurred, and therefore, in reality these systems are of limited value to the operator of the asset. For example, if the system informs that a very large and potentially damaging strike has occurred to a large wind turbine generator, the operator may in reality not make very much use that information. Without knowing where on the wind turbine blade the strike occurred, this data is of no real operational value and a decision on whether to stop the wind turbine generator or to leave it running cannot be taken on the basis this data alone. So, for example, if the operator would be able to receive the information that a large lightning strike had occurred to, say a solid metal tip receptor, then from design and test data it could be determined that this event would represent no threat to the operation of the wind turbine blade. However, if the same strike had occurred to secondary protection such as a surface mesh, then it could be determined that there could be surface damage to the blade, but nothing that would stop its operation. In this case, the wind turbine generator could simply be highlighted for inspection and surface repair at the next scheduled interval. This would be real useful operational information.

U.S. Pat. No. 8,258,773 B2 discloses a system and a method for detecting lightning strikes on a wind turbine blade in which a plurality of lightning receptors are provided on each of the pressure side and suction side. The lighting receptors are electrically coupled to a blade ground conductor which may include multiple components. In an embodiment, each receptor is connected by a branch line to a central line of the blade ground conductor. The central line and the branch line have a gauge suitable for defining a conductive component of the wind turbine's overall ground system for transmitting a lightning strike on any one of the receptors to ground via connection of the blade ground conductor to the wind turbine's main ground conductor. Current sensors are configured with each of the lightning strike receptors. An individual current sensor is configured with the branch line associated with each lightning strike conductor. A current sensor is also configured with the central line. The current sensors are specifically configured to generate a primary current that is proportional to the current that flows through the associated ground conductor in the form of the central line or the branch line as a result of a lightning strike on the respective sensor. This primary current is proportional to the lightning strike current that flows through the central line or the branch line. The current sensors include a core member through which the ground connector runs. The core member is wrapped with a primary winding having a defined number of windings. A common signal converter subsystem is operably associated with each of the current sensors and converts the primary current into a processing signal. The signal converter sub-system may further include one or more secondary current transformers that are arranged in series with the primary current sensor in order to step down the primary current to a signal current. The processing signal is then conveyed to a processing sub-system wherein the processing signal is compared to a threshold value. If the processing signal exceeds the threshold value, a positive indication of a lightning strike on the respective receptor is indicated.

With this system, it would in theory be possible to determine a particular strike location on the blade. However, in order to connect each of the described current sensors with the common signal converter sub-system, physical wiring would be necessary, and this is practically very difficult to implement in a wind turbine. Furthermore, physical wiring would represent a high risk of the detection system itself being damaged by the lighting current it is adapted to measure.

The article “Structural monitoring of wind turbines using wireless sensor networks” by R. Andrew Swartz, Jerome P. Lynch, Stephan Zerbst, Bert Sweetman and Raimund Rolfes, appearing in “Smart Structures and Systems”, Vol. 6, No. 3 (2010) 183-196, presents test installations of wireless sensor technology in wind turbine towers. A number of wireless sensors have been arranged inside each circular hollow steel tower of three different wind turbines at different heights. The objectives of the first instrumentation are to: 1) demonstrate that wireless sensors will operate within the turbine tower, 2) collect and transmit acceleration data, and 3) demonstrate that the data collected compares favourably with similar data collected via a traditional tethered data acquisition (DAQ) system installed in parallel. To accomplish these goals, four wireless sensor nodes are located at different levels within the tower, one at each of the steel platforms; connected to each wireless sensor node are two accelerometers measuring lateral acceleration in orthogonal directions, for a total of eight accelerometers. However, this article is not concerned with detection of lightning strikes, and it is not concerned with sensors placed on the wind turbine blades.

The object of the present invention is to provide a practically realisable and robust lightning detection and measurement system which is adapted to indicate where on the wind turbine blade a lightning strike has occurred.

In view of this object, each individual lightning detector includes an individual sensor element, an individual microprocessor, an individual memory storage, an individual wireless communication module, and an individual power supply including a battery and a power harvesting device adapted to harvest power from one or more sources, such as motion, vibration and light, the system includes a central wireless communication module adapted to wirelessly communicate directly with one or more of the individual wireless communication modules, and each individual wireless communication module is adapted to wirelessly communicate directly with at least one of the other individual wireless communication modules and/or the central wireless communication module.

In this way, each individual microprocessor may in an energy efficient way wirelessly communicate a lightning parameter indicative of the magnitude of a lightning current flowing through an individual electrically conductive part of the system to the central wireless communication module, and the limited energy needed for the wireless communication may be supplied by means of a power harvesting device so that no wiring is necessary for the energy supply. By avoiding any wiring between the individual sensor elements and the central communication module, the communication may easily be implemented and the risk of the detection system itself being damaged by the lighting current it is adapted to measure is minimised.

In an embodiment, each individual wireless communication module is adapted to wirelessly communicate directly with any of the other individual wireless communication modules and the central wireless communication module. Thereby, in the case that wireless communication is not possible directly between a certain individual wireless communication module and the central wireless communication module, an indirect wireless communication may be established between these modules via one or more other individual wireless communication module or modules.

In an embodiment, the system is adapted to, in case of reduced power level of an individual power supply of a respective individual wireless communication module, provide wireless communication indirectly between said respective individual wireless communication module and the central wireless communication module in that said wireless communication is provided via one of the other individual wireless communication modules. Thereby, although the reduced power level of the individual power supply of said respective individual wireless communication module may not allow this individual wireless communication module to communicate with the possibly relatively more remote central wireless communication module, it may still be able to communicate with a relatively nearer located other individual wireless communication module and thereby establish an indirect wireless communication with the central wireless communication module.

In a structurally particularly advantageous embodiment, the individual sensor elements have the form of a Hall effect sensor.

In an embodiment, the main blade ground conductor lightning detector is adapted to be supplied with electrical power from an external power supply of an associated wind turbine. Thereby, the main blade ground conductor lightning detector may be adapted to provide more precise measurements and measurements of different variables, which may require relatively more power, in order to provide a relatively more precise characterisation of the total lightning current leaving the wind turbine blade.

In a structurally particularly advantageous embodiment, the main blade ground conductor lightning detector includes a main blade sensor element, main blade microprocessor, a main blade memory storage, and a main blade wireless communication module.

In an embodiment, the main blade wireless communication module is adapted to wirelessly communicate with each individual wireless communication module and possibly the central wireless communication module. Thereby, the main blade wireless communication module may send its measurements wirelessly to the central wireless communication module. Furthermore, the main blade wireless communication module may possibly be employed to establish an indirect wireless communication between one or more individual wireless communication modules and possibly between these and the central wireless communication module. Furthermore, in the case that the main blade ground conductor lightning detector is adapted to be supplied with electrical power from an external power supply of an associated wind turbine, the main blade wireless communication module may be adapted to send relatively more powerful wireless signals and receive relatively weaker wireless signals, as compared to the wireless signals sent and received by the individual wireless communication modules of the respective individual lightning detectors, thereby enabling wireless communication with individual wireless communication modules located at a relatively longer distance from the main blade wireless communication module, and/or thereby enabling wireless communication with individual wireless communication modules of which the individual power supply has a reduced power level. Thereby, although a reduced power level of the individual power supply of an individual wireless communication module may not allow this individual wireless communication module to communicate with the possibly relatively remote central wireless communication module, it may still be able to communicate with the main blade wireless communication module and thereby establish an indirect wireless communication with the central wireless communication module.

In a structurally particularly advantageous embodiment, the main blade sensor element has the form of a Rogowski coil.

In an embodiment, each individual lightning detector is integrated into an electrically insulated lightning receptor block adapted to be embedded in the wind turbine blade, and an individual electrically conductive part of the system and/or one or more lightning receptors is/are integrated into said electrically insulated lightning receptor block. Thereby, the lightning detection system and the associated lightning protection system may as an integral component or components in the form of said electrically insulated lightning protection receptor blocks be integrated into the wind turbine blade during the production of the wind turbine blade.

In a structurally particularly advantageous embodiment, the lightning receptors include a blade tip lightning receptor and/or a number of surface protection lightning receptors.

In a structurally particularly advantageous embodiment, the lightning receptors include at least one side lightning receptor electrically connected to the blade lightning ground conductor by means of a side receptor lightning conductor branch, and an individual side lightning detector is adapted to measure a lightning parameter indicative of the magnitude of a lightning current flowing through said side receptor lightning conductor branch when a lightning strikes said at least one side lightning receptor. Thereby, said individual side lightning detector may directly measure a lightning parameter indicative of the magnitude of a lightning current received by said at least one side lightning receptor.

In a structurally particularly advantageous embodiment, the lightning detectors include at least one individual central lightning detector associated with the blade lightning ground conductor and being adapted to measure a lightning parameter indicative of the magnitude of a lightning current flowing through an individual part of the blade lightning ground conductor when a lightning strikes one or more of the lightning receptors, and said individual part of the blade lightning ground conductor forms an electrical connection between at least two of the lightning receptors. Thereby, said individual central lightning detector may measure a lightning parameter indicative of the magnitude of a lightning current received by any of the lightning receptors connected to the blade lightning ground conductor at a position from the location of said individual central lightning detector to the blade tip lightning receptor.

In an embodiment, the main blade ground conductor lightning detector is adapted to measure lighting current parameters in terms of one or more, possibly all, of the following parameters: peak current, polarity, charge, rise time and specific energy. Thereby, a relatively more precise characterisation of the total lightning current leaving the wind turbine blade may be provided.

The invention further relates to a wind turbine having a number of wind turbine blades, wherein each wind turbine blade is provided with a lightning detection system according to any one of the preceding claims.

The present invention further relates to a method for detection of lightning strikes on a wind turbine blade, the method including leading a lightning current from one or more of a number of lightning receptors through a blade lightning ground conductor extending in the longitudinal direction of the wind turbine blade, said number of lightning receptors being electrically connected to and distributed along the length of the blade lightning ground conductor, by means of each of a number of individual lightning detectors distributed along the length of the blade lightning ground conductor, measuring a lightning parameter indicative of the magnitude of a lightning current flowing through a corresponding individual electrically conductive part of a connection between a lightning receptor and the blade lightning ground conductor or of the blade lightning ground conductor when said lightning strikes one or more of said number of the lightning receptors, and, by means of a main blade ground conductor lightning detector, measuring at least a magnitude of any lightning current leaving the blade through the blade lightning ground conductor when said lightning strikes said one or more of the lightning receptors.

The method according to the present invention is characterised in that each individual lightning detector measures said lightning parameter by means of an individual sensor element, by means of an individual microprocessor, processes the measured lightning parameter, stores data in an individual memory storage, and controls an individual wireless communication module, by that an individual power supply including a battery and a power harvesting device supplies electrical power to the individual lightning detector, in that the power harvesting device harvests power from one or more sources, such as motion, vibration and light, in that a central wireless communication module included by the system wirelessly communicates directly with one or more of the individual wireless communication modules, and in that each individual wireless communication module wirelessly communicates directly with at least one of the other individual wireless communication modules and/or the central wireless communication module. Thereby, the above-mentioned features may be obtained.

In an embodiment, each individual wireless communication module, when necessary, wirelessly communicates directly with any of the other individual wireless communication modules and the central wireless communication module. Thereby, the above-mentioned features may be obtained.

In an embodiment, in case of reduced power level of an individual power supply of a respective individual wireless communication module, said respective individual wireless communication module communicates wirelessly indirectly with the central wireless communication module via one of the other individual wireless communication modules. Thereby, the above-mentioned features may be obtained.

In an embodiment, the main blade ground conductor lightning detector is supplied with electrical power from an external power supply of an associated wind turbine. Thereby, the above-mentioned features may be obtained.

In an embodiment, the main blade ground conductor lightning detector measures said at least a magnitude of any lightning current leaving the blade by means of a main blade sensor element, by means of a main blade microprocessor, processes the measured at least a magnitude of any lightning current, stores data in a main blade memory storage, and controls a main blade wireless communication module. Thereby, the above-mentioned features may be obtained.

In an embodiment, the main blade wireless communication module, when necessary, wirelessly communicates with any of the individual wireless communication modules and possibly the central wireless communication module. Thereby, the above-mentioned features may be obtained.

In an embodiment, the main blade ground conductor lightning detector measures lighting current parameters in terms of one or more, possibly all, of the following parameters: peak current, polarity, charge, rise time and specific energy. Thereby, the above-mentioned features may be obtained.

In an embodiment, the post processing and analysis of the data is performed by a remote computer, such as a cloud based service, after receiving data from the central wireless communication module in the wind turbine. Algorithms running on the remote computer, analyse the measurements performed by the individual lightning detectors and the main blade ground conductor lightning detector, and, on the basis thereof, provides an indication of the location of the lightning strike or strikes on the wind turbine blade and an indication of the magnitude of the lightning current or currents resulting from of the lightning strike or strikes. This data is then presented as strike magnitude and location information directly to the user by means of a customised web portal.

Thereby, a user of the system may easily plan when and where to perform repair of the wind turbine blade.

The invention will now be explained in more detail below by means of examples of embodiments with reference to the very schematic drawing, in which

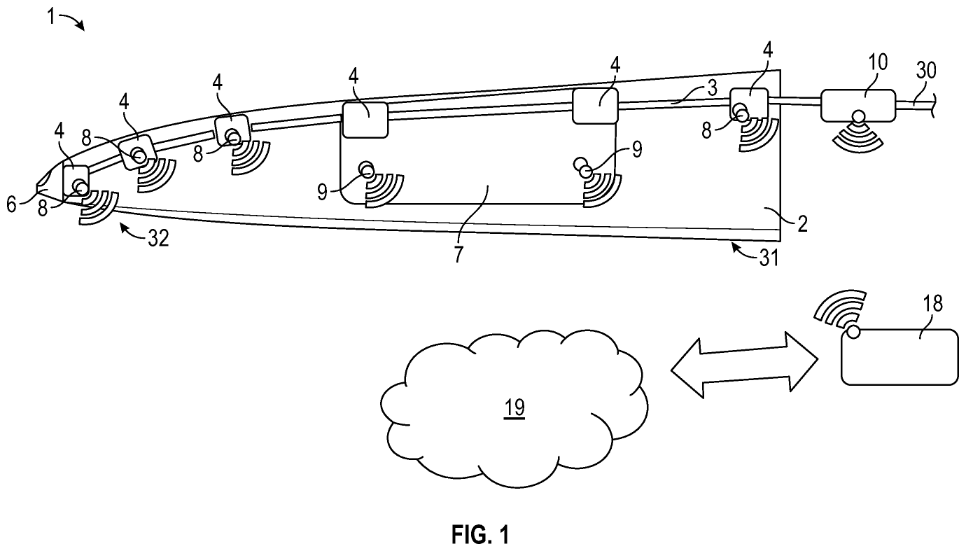

FIG. 1 illustrates an embodiment of a lightning detection system according to the present invention;

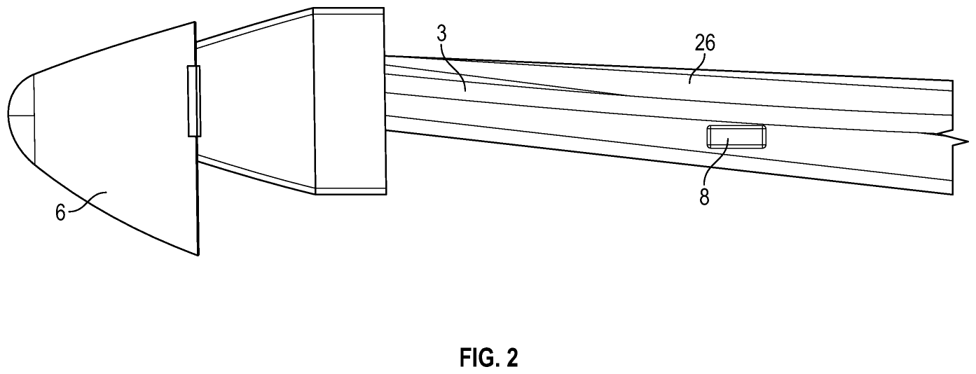

FIG. 2 illustrates a blade tip lightning receptor and an electrically insulated lightning protection tip implant forming part of the lightning detection system of FIG. 1;

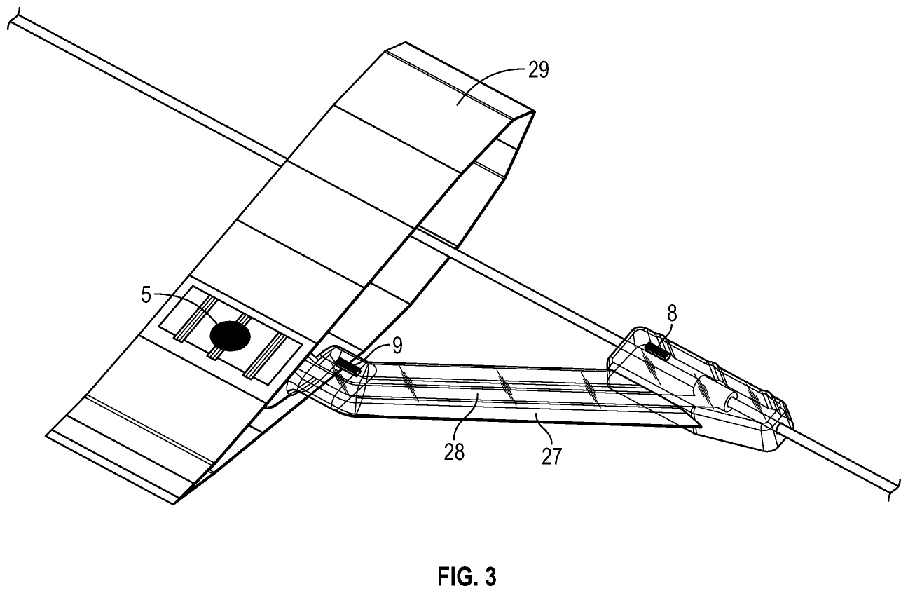

FIG. 3 illustrates a perspective view of an electrically insulated lightning protection side implant forming part of the lightning detection system of FIG. 1;

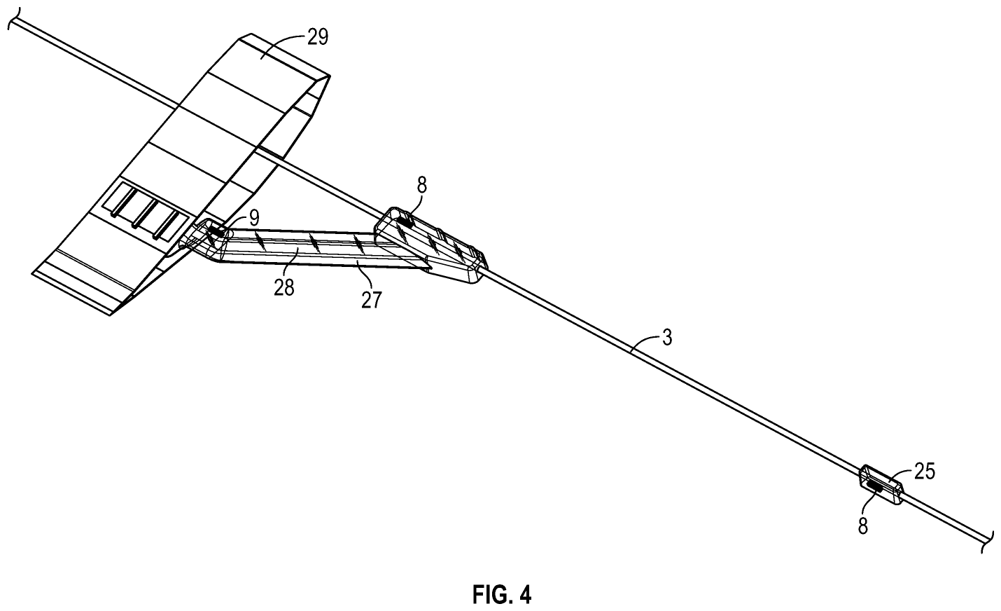

FIG. 4 illustrates a perspective view of an electrically insulated lightning protection side implant and an electrically insulated lightning protection central implant forming part of the lightning detection system of FIG. 1;

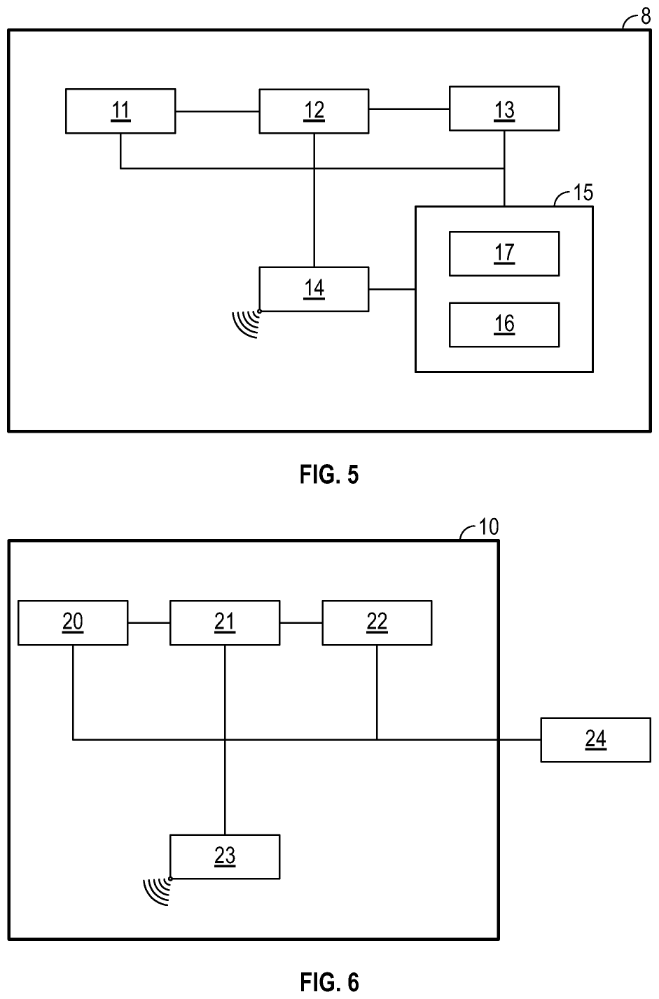

FIG. 5 illustrates an individual central lightning detector forming part of the lightning detection system of FIG. 1; and

FIG. 6 illustrates a main blade ground conductor lightning detector forming part of the lightning detection system of FIG. 1.

FIG. 1 illustrates an embodiment of a lightning detection system 1 according to the present invention adapted to detect lightning strikes on a wind turbine blade 2. The lightning detection system 1 includes a lightning protection system in the form of a blade lightning ground conductor 3 extending in the longitudinal direction of the wind turbine blade 2 and a number of lightning receptors 4, 5, 6, 7 electrically connected to and distributed along the length of the blade lightning ground conductor 3. The end 30 of the blade lightning ground conductor 3 seen to the right in FIG. 1 is adapted to be connected to the main ground conductor of an associated wind turbine (not shown) in order to lead a lightning current received by any of the lightning receptors 4, 5, 6, 7 down into the earth in a way known per se.

A number of individual lightning detectors 8, 9 in the form of so-called smart sensors are distributed in an array along the length of the blade lightning ground conductor 3 and each is adapted to measure a lightning parameter indicative of the magnitude of a lightning current flowing through a corresponding individual electrically conductive part of a connection 28 between a lightning receptor 4, 5, 6, 7 and the blade lightning ground conductor 3 or of the blade lightning ground conductor 3 when a lightning strikes one or more of the lightning receptors 4, 5, 6, 7, as illustrated in the figures. The advantages of the so-called smart sensors are that they are geometrically very small and require no external power or data wiring. Furthermore, a main blade ground conductor lightning detector 10 located at the root end 31 of the wind turbine blade 2 or in a not shown hub of the wind turbine is adapted to measure at least a magnitude of any lightning current leaving the blade 2 through the blade lightning ground conductor 3 when a lightning strikes one or more of the lightning receptors 4, 5, 6, 7.

As illustrated in FIG. 5, each individual lightning detector 8, 9 includes an individual sensor element 11, an individual microprocessor 12, an individual memory storage 13, an individual wireless communication module 14, and an individual power supply 15 including a battery 16 and a power harvesting device 17 adapted to harvest power from one or more sources, such as motion, vibration and light. Power harvesting from motion is preferred, as the wind turbine blade rotates most of the time. However, if the wind turbine blade is not rotating, sources such as vibration are a possibility. However, the battery 16 may store energy to be used during periods in which the power harvesting device 17 does not generate energy.

As illustrated in FIG. 1, the system 1 includes a central wireless communication module 18 adapted to wirelessly communicate directly with one or more of the individual wireless communication modules 14 of the respective individual lightning detectors 8, 9. The central wireless communication module 18 may for instance be located in a not shown tower of the wind turbine, or adjacent the wind turbine, and the central wireless communication module 18 may include a gateway and may communicate with a cloud server 19 via the internet, either via a direct connection or wirelessly.

According to the present invention, each individual wireless communication module 14 of the respective individual lightning detectors 8, 9 is adapted to wirelessly communicate directly with the individual wireless communication module 14 of at least one of the other individual lightning detectors 8, 9 and/or with the central wireless communication module 18.

Each individual microprocessor 12 may thereby in an energy efficient way wirelessly communicate a lightning parameter indicative of the magnitude of a lightning current flowing through an individual electrically conductive part 3, 28 of the system 1 to the central wireless communication module 18, and the limited energy needed for the wireless communication may be supplied by means of the power harvesting device 17 so that no wiring is necessary for the energy supply. By avoiding any wiring between the individual sensor elements 11 and the central communication module 18, the communication may easily be implemented and the risk of the detection system 1 itself being damaged by the lighting current it is adapted to measure is minimised.

It is preferred that each individual wireless communication module 14 is adapted to wirelessly communicate directly with any of the other individual wireless communication modules 14 and the central wireless communication module 18. Thereby, in the case that wireless communication is not possible directly between a certain individual wireless communication module 14 and the central wireless communication module 18, an indirect wireless communication may be established between these modules 14, 18 via one or more other individual wireless communication modules.

Preferably, the system 1 is adapted to, in case of reduced power level of an individual power supply 15 of a respective individual wireless communication module 14, provide wireless communication indirectly between said respective individual wireless communication module 14 and the central wireless communication module 18 in that said wireless communication is provided via one of the other individual wireless communication modules 14. Thereby, although the reduced power level of the individual power supply 15 of said respective individual wireless communication module 14 may not allow this individual wireless communication module 14 to communicate with the possibly relatively more remote central wireless communication module 18, it may still be able to communicate with a relatively nearer located other individual wireless communication module 14 and thereby establish an indirect wireless communication with the central wireless communication module 18.

It may be preferred that the main blade ground conductor lightning detector 10 is adapted to be supplied with electrical power from an external power supply 24 of an associated wind turbine, as illustrated in FIG. 6. Thereby, the main blade ground conductor lightning detector 10 may be adapted to provide more precise measurements and measurements of different variables, which may require relatively more power. In fact, it is preferred that the main blade ground conductor lightning detector 10 is adapted to measure lighting current parameters in terms of one or more, possibly all, of the following parameters: peak current, polarity, total charge transfer, rise time, pulse shape and specific energy. Thereby, a relatively more precise characterisation of the total lightning current leaving the wind turbine blade 2 may be provided by the system 1.

In the embodiment illustrated in FIG. 6, the main blade ground conductor lightning detector 10 includes a main blade sensor element 20, main blade microprocessor 21, a main blade memory storage 22, and a main blade wireless communication module 23. The main blade wireless communication module 23 is adapted to wirelessly communicate with each individual wireless communication module 14 and possibly the central wireless communication module 18. If the main blade ground conductor lightning detector 10 is supplied with electrical power from an external power supply 24, a cable connection from the main blade ground conductor lightning detector 10 is required anyway, and for instance in this case, the main blade microprocessor 21 may alternatively communicate directly via a cable connection with the central wireless communication module 18.

It is preferred that the individual sensor elements 11 of the individual lightning detectors 8, 9 have the form of a Hall effect sensor placed in the vicinity of the relevant individual electrically conductive part through which a lightning current to be measured flows. The Hall effect sensor measures the signature of the magnetic field caused by the lightning current flow. However, the individual sensor element 11 may be any kind of sensor suitable to measure a lightning parameter indicative of the magnitude of a lightning current flowing through a corresponding individual electrically conductive part of the system 1. In addition or alternatively, the individual sensor element 11 may include other kinds of sensors, such as an accelerometer, a vibration measuring device, a shock measuring device, a temperature measuring device, etc. Furthermore, it is preferred that the main blade sensor element 20 of the main blade ground conductor lightning detector 10 has the form of a Rogowski coil encircling the blade lightning ground conductor 3 at the position where the lightning current to be measured flows. However, the main blade sensor element 20 may be any kind of sensor suitable to measure lighting current parameters in terms of one or more, possibly all, of the following parameters: peak current, polarity, charge, rise time and specific energy of a lightning current flowing through a corresponding individual electrically conductive part of the blade lightning ground conductor 3. In addition or alternatively, the main blade sensor element 20 may include other kinds of sensors, such as an accelerometer, a vibration measuring device, a shock measuring device, a temperature measuring device, etc. The main blade ground conductor lightning detector 10 may utilise a much faster processor and larger storage capacity which enables precision measurement of the lightning event parameters. On the basis of the above, it is understood that a large amount of data on the condition of the wind turbine blade 2 with respect to lighting strike can be gathered and collated, further improving future operational planning.

As illustrated in FIGS. 2, 3 and 4, each individual lightning detector 8, 9 is integrated into an electrically insulated lightning protection implant 25, 26, 27 adapted to be embedded in the wind turbine blade 2, and an individual electrically conductive part 3, 28 of the system 1 and/or one or more lightning receptors 4, 5 is/are integrated into said electrically insulated lightning protection implant 25, 26, 27. Thereby, the lightning detection system 1 and the associated lightning protection system may as an integral component or components in the form of said electrically insulated lightning protection implant or implants 25, 26, 27 be integrated into the wind turbine blade 2 during the production of the wind turbine blade. The surface lightning receptors 4, 5 are typically embedded in the laminate of the wind turbine blade 2.

As illustrated in FIG. 1, the lightning receptors include a blade metal tip lightning receptor 6 arranged at the tip end 32 of the wind turbine blade 2 and/or a number of surface protection lightning receptors 4, 5, 7.

As further illustrated in FIGS. 3 and 4, the lightning receptors include at least one side lightning receptor 5 electrically connected to the blade lightning ground conductor 3 by means of a side receptor lightning conductor branch 28, and an individual side lightning detector 9 is adapted to measure a lightning parameter indicative of the magnitude of a lightning current flowing through said side receptor lightning conductor branch 28 when a lightning strikes said at least one side lightning receptor 5. Thereby, said individual side lightning detector 9 may directly measure a lightning parameter indicative of the magnitude of a lightning current received by said at least one side lightning receptor 5.

As further illustrated in FIGS. 3 and 4, the lightning detectors include at least one individual central lightning detector 8 associated with the blade lightning ground conductor 3 and being adapted to measure a lightning parameter indicative of the magnitude of a lightning current flowing through an individual part of the blade lightning ground conductor 3 when a lightning strikes one or more of the lightning receptors 4, 5, 6, 7, and said individual part of the blade lightning ground conductor 3 forms an electrical connection between at least two of the lightning receptors. Thereby, said individual central lightning detector 8 may measure a lightning parameter indicative of the magnitude of a lightning current received by any of the lightning receptors 4, 5, 6 connected to the blade lightning ground conductor 3 at a position from the location of said individual central lightning detector 8 to the blade tip lightning receptor 6.

According to an embodiment of the present invention, a not shown wind turbine has a number of wind turbine blades 2, wherein each wind turbine blade 2 is provided with a lightning detection system 1 as described above. However, advantageously a common lightning detection system 1 for all wind turbine blades 2 of the wind turbine may be provided in which one common central wireless communication module 18 and one common cloud server 19 is provided. In the same way, when more wind turbines are provided with a lightning detection system 1 according to the invention, advantageously a common lightning detection system 1 for all wind turbine blades 2 of the several wind turbines may be provided with one common cloud server 19. If some of the wind turbines are located relatively near each other, possibly one common central wireless communication module 18 may be provided for those wind turbines.

The present invention furthermore relates to a method for detection of lightning strikes on a wind turbine blade 2 such as the one illustrated in FIG. 1. The method includes leading a lightning current from one or more of the lightning receptors 4, 5, 6, 7 through the blade lightning ground conductor 3 extending in the longitudinal direction of the wind turbine blade 2. By means of each of the individual lightning detectors 8, 9 distributed along the length of the blade lightning ground conductor 3, a lightning parameter indicative of the magnitude of a lightning current flowing through a corresponding individual electrically conductive part of a respective connection 28 between a lightning receptor 4, 5, 6, 7 and the blade lightning ground conductor 3 or of the blade lightning ground conductor 3 is measured when said lightning strikes one or more of said number of the lightning receptors 4, 5, 6, 7. By means of the main blade ground conductor lightning detector 10, at least a magnitude of any lightning current leaving the blade 2 through the blade lightning ground conductor 3 is measured when said lightning strikes said one or more of the lightning receptors 4, 5, 6, 7. Each individual lightning detector 8, 9 measures said lightning parameter by means of the individual sensor element 11, by means of the individual microprocessor 12, processes the measured lightning parameter, stores data in the individual memory storage 13, and controls the individual wireless communication module 14. The individual power supply 15 including the battery 16 and the power harvesting device 17 supplies electrical power to the individual lightning detector 8, 9. The power harvesting device 17 harvests power from one or more sources, such as motion, vibration and light. The central wireless communication module 18 included by the system 1 communicates wirelessly directly with one or more of the individual wireless communication modules 14, and each individual wireless communication module 14 communicates wirelessly directly with at least one of the other individual wireless communication modules 14 and/or the central wireless communication module 18.

In an embodiment, when necessary, each individual wireless communication module 14 communicates wirelessly directly with any of the other individual wireless communication modules 14 and the central wireless communication module 18.

In an embodiment, in case of reduced power level of an individual power supply 15 of a respective individual wireless communication module 14, said respective individual wireless communication module 14 communicates wirelessly indirectly with the central wireless communication module 18 via one of the other individual wireless communication modules 14.

In an embodiment, the main blade ground conductor lightning detector 10 measures said at least a magnitude of any lightning current leaving the blade 2 by means of a main blade sensor element 20, by means of a main blade microprocessor 21, processes the measured at least a magnitude of any lightning current, stores data in a main blade memory storage 22, and controls a main blade wireless communication module 23.

In an embodiment, when necessary, the main blade wireless communication module 23, communicates wirelessly with any of the individual wireless communication modules 14 and possibly the central wireless communication module 18.

In an embodiment, the wireless communication between each individual wireless communication module 14, the main blade wireless communication module 23 and the central wireless communication module 18 is performed by means of ZigBee (Registered Trademark) devices.

In an embodiment, the main blade ground conductor lightning detector 10 measures lighting current parameters in terms of one or more, possibly all, of the following parameters: peak current, polarity, charge, rise time and specific energy.

In an embodiment, a computer, such as a cloud server 19, receives data from the central wireless communication module 18 and compares the measurements performed by the individual lightning detectors 8, 9 and the main blade ground conductor lightning detector 10, and, on the basis thereof, provides an indication of the location of the lightning strike or strikes on the wind turbine blade 2 and an indication of the magnitude of the lightning current or currents resulting from of the lightning strike or strikes. The central wireless communication module 18 may package up the raw data from the individual central lightning detectors 8, 9 and the main blade ground conductor lightning detector 10 and transmit the data to the cloud server 19. The data packets may indicate date and time of event, sensor readings from all individual sensor elements 11 and the main blade sensor element 20, wind turbine identification (ID) and wind turbine blade identification (ID).

Then, because the cloud server 19 is programmed with the design data for the specific wind turbine blade 2 and lightning protection system 1, it can make an accurate assessment on potential expected damage to the wind turbine blade 2. The cloud server 19 then may update this information in real time to an operation centre for the asset in question. This output can also be configured to simultaneously send alerts or warnings to smart devices such as phones or tablets. In this way, the operator has a real meaningful assessment of the lightning event and is able to make an informed decision on the operational planning. The lightning protection system 1 thereby may enable real targeted preventative maintenance and repair strategies, prevent false shut-downs, increase operation time and reduce operational expenditure.

### LIST OF REFERENCE NUMBERS

1 lightning protection system
2 wind turbine blade
3 blade lightning ground conductor
4 lightning receptor
5 side lightning receptor
6 blade tip lightning receptor
7 surface protection lightning receptors
8 individual central lightning detector
9 individual side lightning detector
10 main blade ground conductor lightning detector
11 individual sensor element
12 individual microprocessor
13 individual memory storage
14 individual wireless communication module
15 individual power supply
16 battery
17 power harvesting device
18 central wireless communication module
19 cloud server
20 main blade sensor element
21 main blade microprocessor
22 main blade memory storage
23 main blade wireless communication module
24 external power supply of wind turbine
25 electrically insulated lightning protection central implant
26 electrically insulated lightning protection tip implant
27 electrically insulated lightning protection side implant
28 side receptor lightning conductor branch
29 lightning protection implant
30 end of blade lightning ground conductor
31 root end of wind turbine blade
32 tip end of wind turbine blade

1. A lightning detection system adapted to detect lightning strikes on a wind turbine blade, the system including a blade lightning ground conductor adapted to extend in the longitudinal direction of a wind turbine blade, a number of lightning receptors electrically connected to and distributed along the length of the blade lightning ground conductor, a number of individual lightning detectors distributed along the length of the blade lightning ground conductor and each being adapted to measure a lightning parameter indicative of the magnitude of a lightning current flowing through a corresponding individual electrically conductive part of a connection between a lightning receptor and the blade lightning ground conductor or of the blade lightning ground conductor when a lightning strikes one or more of the lightning receptors, and a main blade ground conductor lightning detector adapted to measure at least a magnitude of any lightning current leaving the blade through the blade lightning ground conductor when a lightning strikes one or more of the lightning receptors, wherein each individual lightning detector includes an individual sensor element, an individual microprocessor, an individual memory storage, an individual wireless communication module, and an individual power supply including a battery and a power harvesting device adapted to harvest power from one or more sources, such as motion, vibration and light, in that the system includes a central wireless communication module adapted to wirelessly communicate directly with one or more of the individual wireless communication modules, and in that each individual wireless communication module is adapted to wirelessly communicate directly with at least one of the other individual wireless communication modules and/or the central wireless communication module.

2. A lightning detection system according to claim 1, wherein each individual wireless communication module is adapted to wirelessly communicate directly with any of the other individual wireless communication modules and the central wireless communication module.

3. A lightning detection system according to claim 1, wherein the system is adapted to, in case of reduced power level of an individual power supply of a respective individual wireless communication module, provide wireless communication indirectly between said respective individual wireless communication module and the central wireless communication module in that said wireless communication is provided via one of the other individual wireless communication modules.

4. A lightning detection system according to claim 1, wherein the individual sensor elements are capable of measuring the lightning current, such as e.g. a Hall effect sensor.

5. A lightning detection system according to claim 1, wherein the main blade ground conductor lightning detector is adapted to be supplied with electrical power from an external power supply of an associated wind turbine.

6. A lightning detection system according to claim 1, wherein the main blade ground conductor lightning detector includes a main blade sensor element, main blade microprocessor, a main blade memory storage, and a main blade wireless communication module.

7. A lightning detection system according to claim 6, wherein the main blade wireless communication module is adapted to wirelessly communicate with each individual wireless communication module and possibly the central wireless communication module.

8. A lightning detection system according to claim 5, wherein the main blade sensor element is capable of measuring the lightning current, such as e.g. a Rogowski coil.

9. A lightning detection system according to claim 1, wherein each individual lightning detector is integrated into an electrically insulated lightning protection implant adapted to be embedded in the wind turbine blade, and wherein an individual electrically conductive part of the system and/or one or more lightning receptors is/are integrated into said electrically insulated lightning protection implant.

10. A lightning detection system according to claim 1, wherein the lightning receptors include a blade tip lightning receptor and/or a number of surface protection lightning receptors.

11. A lightning detection system according to claim 1, wherein the lightning receptors include at least one side lightning receptor electrically connected to the blade lightning ground conductor by means of a side receptor lightning conductor branch, and wherein an individual side lightning detector is adapted to measure a lightning parameter indicative of the magnitude of a lightning current flowing through said side receptor lightning conductor branch when a lightning strikes said at least one side lightning receptor.

12. A lightning detection system according to claim 1, wherein the lightning detectors include at least one individual central lightning detector associated with the blade lightning ground conductor and being adapted to measure a lightning parameter indicative of the magnitude of a lightning current flowing through an individual part of the blade lightning ground conductor when a lightning strikes one or more of the lightning receptors, and wherein said individual part of the blade lightning ground conductor forms an electrical connection between at least two of the lightning receptors.

13. A lightning detection system according to claim 1, wherein the main blade ground conductor lightning detector is adapted to measure lighting current parameters in terms of one or more, possibly all, of the following parameters: peak current, polarity, charge, rise time and specific energy.

14. A wind turbine having a number of wind turbine blades, wherein each wind turbine blade is provided with a lightning detection system according to claim 1.

15. A method for detection of lightning strikes on a wind turbine blade, the method including leading a lightning current from one or more of a number of lightning receptors through a blade lightning ground conductor extending in the longitudinal direction of the wind turbine blade, said number of lightning receptors being electrically connected to and distributed along the length of the blade lightning ground conductor, by means of each of a number of individual lightning detectors distributed along the length of the blade lightning ground conductor, measuring a lightning parameter indicative of the magnitude of a lightning current flowing through a corresponding individual electrically conductive part of a connection between a lightning receptor and the blade lightning ground conductor or of the blade lightning ground conductor when said lightning strikes one or more of said number of the lightning receptors, and, by means of a main blade ground conductor lightning detector, measuring at least a magnitude of any lightning current leaving the blade through the blade lightning ground conductor when said lightning strikes said one or more of the lightning receptors, wherein each individual lightning detector measures said lightning parameter by means of an individual sensor element, by means of an individual microprocessor, processes the measured lightning parameter, stores data in an individual memory storage, and controls an individual wireless communication module, by that an individual power supply including a battery and a power harvesting device supplies electrical power to the individual lightning detector, in that the power harvesting device harvests power from one or more sources, such as motion, vibration and light, in that a central wireless communication module included by the system wirelessly communicates directly with one or more of the individual wireless communication modules, and in that each individual wireless communication module wirelessly communicates directly with at least one of the other individual wireless communication modules and/or the central wireless communication module.

16. A method for detection of lightning strikes on a wind turbine blade according to claim 15, whereby each individual wireless communication module, when necessary, wirelessly communicates directly with any of the other individual wireless communication modules and the central wireless communication module.

17. A method for detection of lightning strikes on a wind turbine blade according to claim 15, whereby, in case of reduced power level of an individual power supply of a respective individual wireless communication module, said respective individual wireless communication module communicates wirelessly indirectly with the central wireless communication module via one of the other individual wireless communication modules.

18. A method for detection of lightning strikes on a wind turbine blade according to claim 15, whereby the main blade ground conductor lightning detector is supplied with electrical power from an external power supply of an associated wind turbine.

19. A method for detection of lightning strikes on a wind turbine blade according to claim 15, whereby the main blade ground conductor lightning detector measures said at least a magnitude of any lightning current leaving the blade by means of a main blade sensor element, by means of a main blade microprocessor, processes the measured at least a magnitude of any lightning current, stores data in a main blade memory storage, and controls a main blade wireless communication module.

20. A method for detection of lightning strikes on a wind turbine blade according to claim 19, whereby the main blade wireless communication module, when necessary, wirelessly communicates with any of the individual wireless communication modules and possibly the central wireless communication module.

21-22. (canceled)
